(19) United States
(12) Patent Application Publication
(10) Pub. No.: US 2022/0145446 A1
(43) Pub. Date: May 12, 2022

(54) METHOD FOR PRODUCING TARGETS FOR PHYSICAL VAPOR DEPOSITION (PVD)

(71) Applicant: Oerlikon Surface Solutions AG, Pfäffikon, Pfäffikon (CH)

(72) Inventors: Arkadi ZIKIN, Wohlen (CH); Beno WIDRIG, Bad Ragaz (CH); Juergen RAMM, Maienfeld (CH); Stefan ANDRES, Rotkreuz (CH)

(21) Appl. No.: 17/433,203

(22) PCT Filed: Feb. 24, 2020
(86) PCT No.: PCT/EP2020/054779

§ 371 Date: Aug. 23, 2021

Related U.S. Application Data
(60) Provisional application No. 62/809,035, filed on Feb. 22, 2019.

(51) Int. Cl. C23C 14/34; H01J 37/34

(52) U.S. Cl. CPC C23C 14/3414; H01J 37/3435

(57) ABSTRACT

Method for building up and/or finalizing a PVD target whereas the method comprises a process step where target material is added using an additive method.

The present invention relates to a method for the production of targets to be used for PVD in coating machines.

PVD targets are used for many different physical vapor deposition processes in order to deposit thin films onto substrates. The most prominent among these processes are arc-deposition and sputtering. In both processes the target is used as cathode. And in both cases the targets are put into a coating chamber which during the deposition process is evacuated.

For arc deposition, electrons are generated in an arc spot at the cathode (=target) and drawn to an anode. The arc spot, moving at the target surface in a more or less random manner, heats the area of the spot at the target surface and the target material is evaporated almost in an explosive manner. During the coating process substrates to be coated are positioned opposite to the target surface in such a manner that the evaporated particles are deposited onto the surface of the substrates to be coated. As a major part of the evaporated particles are ionized, a negative bias applied to the substrates (in relation to the target) will even accelerate the particles onto the substrate thereby leading to coating layers with high density, which constitutes one of the advantages of this coating method. Quite often however not only particles/ions are evaporated form the target surface, but due to the high temperature impact surface material is molten forming droplets which as well are ejected and deposited onto the substrate surface to be coated. For some applications this is a disadvantage as such droplets form discontinuities on the substrate surface which sometimes tend to break away, thereby forming holes into the coating layer.

There are different and efficient ways to avoid the droplet problem such as filtering and/or pulsing. However this has impact on the economics of the coating process such as for example decrease of the deposition rate.

For sputtering positive ions from a working gas (such as for example argon) are created in front of the target surface. As a high negative voltage is applied to the target, the ions are accelerated in direction to the target surface and are impinging onto the target surface and vaporize/knock-out the material of the target surface by their impact. This vaporization process which is based on the ionized working gas, however, does form standard sputtering only little ionized metallic vapor (in contrast to cathodic arc evaporation). During the coating process, substrates to be coated are positioned opposite to the sputter target surface in such a manner that the vaporized target material is deposited onto the surface of the substrates to be coated.

One advantage of the sputtering process is that if the process is conducted in a proper manner, thereby avoiding to much arcing, no droplets are formed and the coated layer will be homogeneous and smooth. One disadvantage, however is if the conventional sputtering power is used, that the vaporized particles in their majority are not ionized. Therefore, biasing the substrates by a negative potential does only increase the energy of the working gas ions but does not alter or increase the atoms of the vaporized target material. The increase of the energy of the working gas (e.g. argon) may help to increase the density of the coating but also may result in sputtering of the substrate surface and the synthesized coating at the substrate surface.

In order to realize a high percentage of ionized particles with sputtering it is known that very high sputtering power can be used. Unfortunately the energy input into the target is as well very high during the process and the temperature of the target increases dramatically fast, thereby destroying the target in a short time. In order to avoid this, the power is pulsed, thereby interrupting the energy input and giving the target time to cool down again. This however as well has negative impact on coating economics such as for example deposition rate.

Key to all these methods is therefore that there is an excellent contact between the plate provided to carry the target material and the “plate” of the holder on which the target is “mounted”. Contact in this context means mechanical contact and/or thermal contact and/or electrical contact. An excellent mechanical contact in this context means that the plate which carries the target material and the surface of the target holder at which the target is attached to for operation, there is no gap and the holder is constructed in a manner that bending of the target is not possible.

An excellent thermal contact in this context means that between the plate provided to carry the target material and the plate of the holder to which the target is attached to and which is cooled, only a negligible temperature difference can be measured in the contact area between these two surfaces. [symbol] _{[RJ(L1]}Additional external pressure can be applied to increase the contact pressure between target plate and holder to improve the thermal contact.

An excellent electrical contact in this context means that between the plate provided to carry the target material and the holder to which the target is attached to, the electrical resistance I less than 1 Ohm, more preferred less than 0.1 Ohm, more preferred less than 0.05 Ohm. [symbol] _{[RJ(L2]}
The mechanical contact should be good in order not to allow the target surface to be deformed if temperature gradients are acting upon the target surface, for example due to the localized energy impact during arc evaporation.
The thermal contact should be good in order to guarantee rapid and efficient cooling of the target, which is heated due to the extreme energy impact during for example high power pulsed magnetron sputtering.
The electrical contact should be good in any case in order to use the target as cathode surface during the deposition process.

In order to produce PVD targets, different technologies are used. Known methods can be basically divided into powder metallurgical methods and methods based on metal melting. For powder metallurgical methods there are many different possibilities, which are used and need to be chosen according to the composition of the desired target, taking into account the characteristics of the elements to be integrated. Examples are pressing (such as for example hot isostatic pressing) or sintering, welding, rolling, hot pressing and spark plasma sintering or a combination thereof.

One problem of all these PVD target manufacturing methods is that the target material itself is produced separate from the base plate it needs to be mounted and in particular be in good mechanical, thermal as well as electrical contact. This mounting requires an elaborate second step, which makes the whole process complicated, expensive and sometimes—especially if brittle target materials are involved—reduces production yield considerably.

Another problem is that at least if targets are used for magnetron sputtering, material is mainly taken from the target along the so called race track. After a while grove along this track are formed which, if they become too deep render the target unusable, despite the fact that there is still a lot of material outside the groove as described. As target material is quite expensive, yield of target material usage plays a major role.

Therefore, there is the need for a target manufacturing method which at least partially overcomes the deficiencies of prior art as just described.

It is therefore an objective of the present invention to at least partially overcome these problems.

According to the present invention the manufacturing method comprises a process step where target material is added using an additive method:

According to one aspect of the present invention, target material is added by thermal spray methods.

According to second aspect of the present invention, target material is added by conventional laser cladding

According to a third aspect of the present invention, target material is added by extreme high-speed laser cladding (EHLA Extremes Hochgeschwindigkeits Laser Auftragsschweissen). This is extremely efficient if disc shaped targets need to be produced as they do have a rotational symmetry.

According to a fourth aspect of the present invention, target material is added by a 3D printing method. This is especially effective if the target material needs to have an inner structure such as for example micro-gaps. Such gaps can be used to render the target more temperature resistant. The principle itself is described in WO20151971696. However in WO20151971696 randomly distributed micro-gaps are used whereas the additive method and in particular the 3D printing method allows for predefined micro-gaps in the target. Another advantage is that with 3D printing in the target material itself cooling channels for water cooling or air cooling can be foreseen which allows for a very efficient cooling approach.

Another aspect of the present invention is target repair and/or target refill: Apart from completely building the material with an additive method, material may be partially added by one or more of these methods. It is as well possible to combine conventional target manufacturing methods such as sintering and/or hot isostatic pressing with one or more of these additive methods.

It is for example possible to locally refill the race track groove by an additive method. Used targets may therefore be reconditioned in order to be able to use them again. It is not necessary to start with a completely new target, building it up from the base. And it is as well not necessary to strip the remaining target material from the base plate in order to recover it. In this context conventional laser cladding, thermal spraying or 3D printing is especially efficient.

In the case of arc targets it sometimes happens that due to some process defect holes are burned into the target plate. The additive step according to the present invention allows to repair such a target.

According to another aspect of the present invention it is possible to use material combinations which up to now were difficult or even impossible to combine. If the additive method is based on powder material, powder mixtures may be used in order to perform the additive step to build up or finalize the target plate.

The present invention will now be described in detail on the basis of not limiting examples and with the help of the figures as shown.

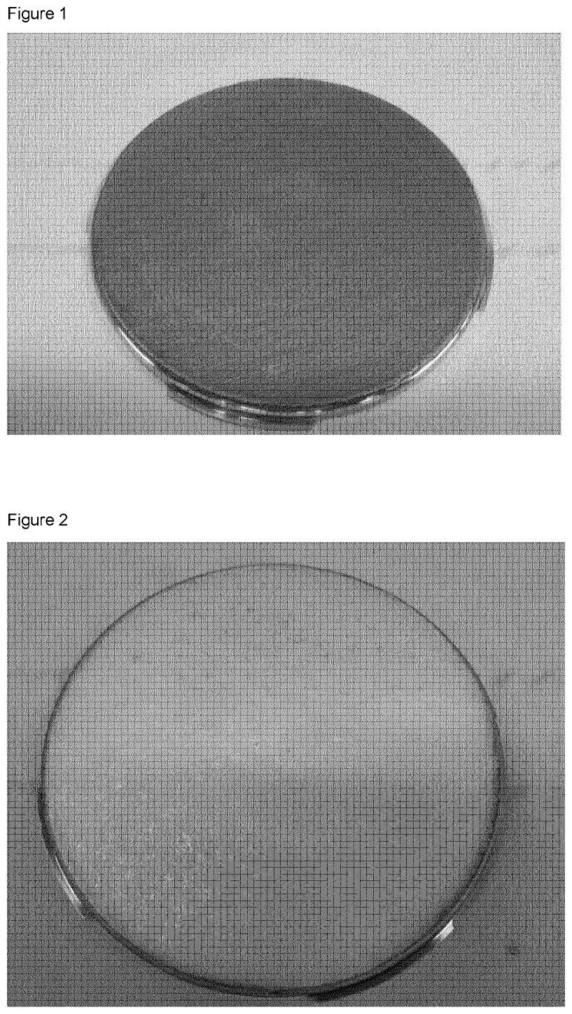

FIG. 1 shows a target before the process.

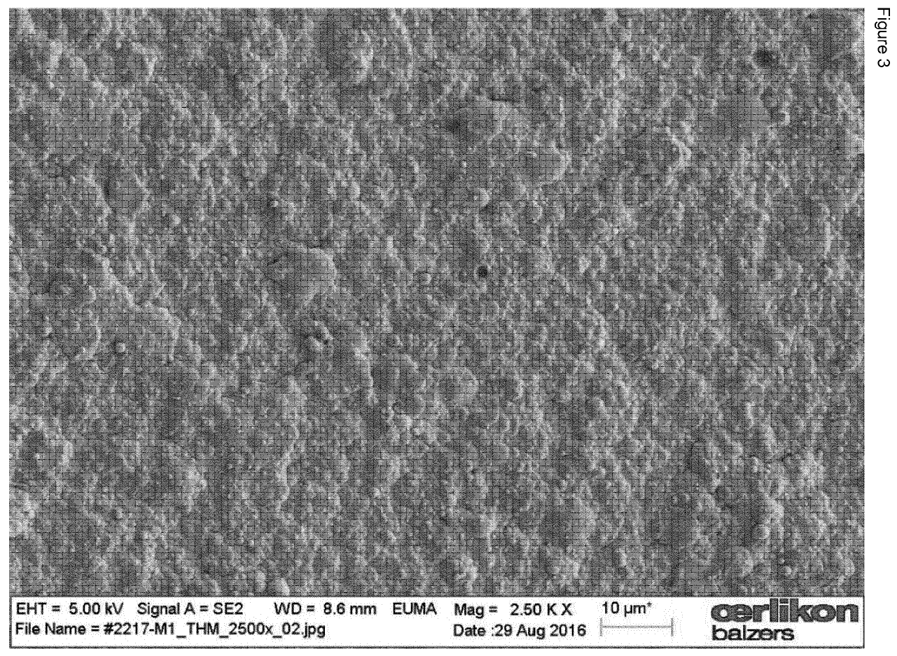

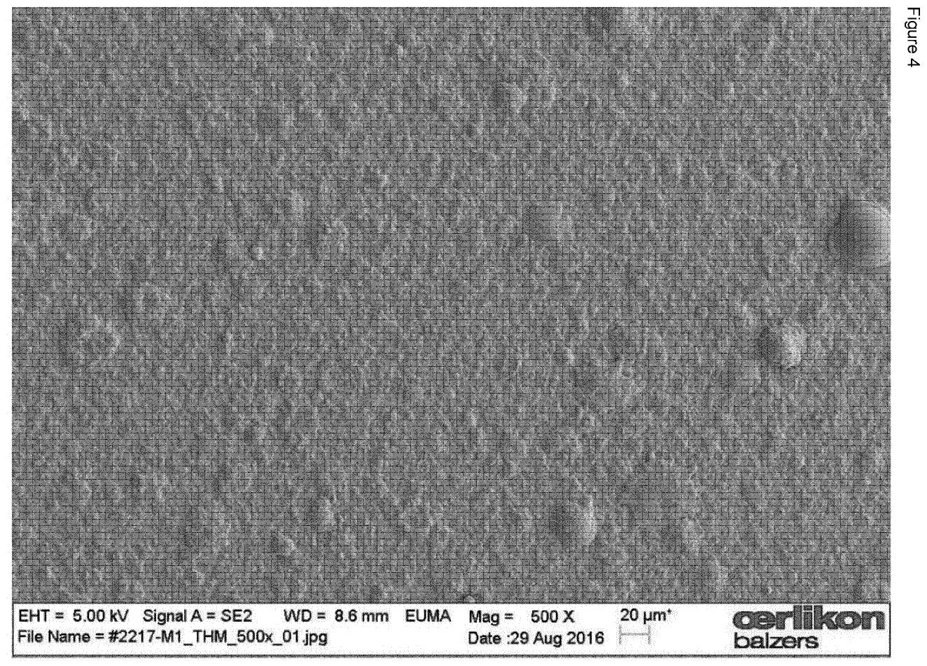

FIG. 2 shows a target after the process.

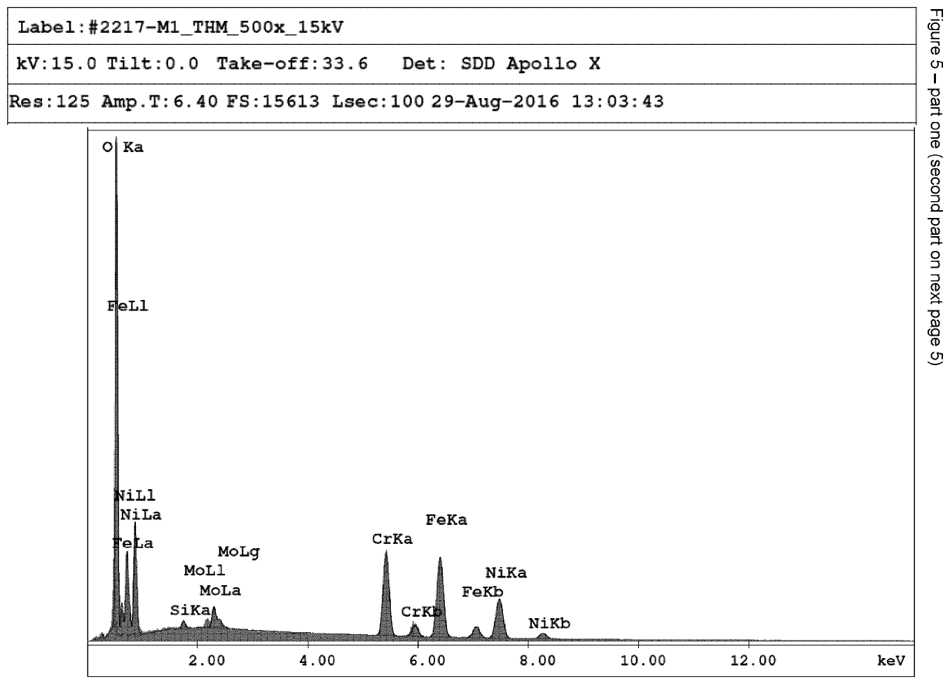

FIG. 3 shows the surface of a coated layer.

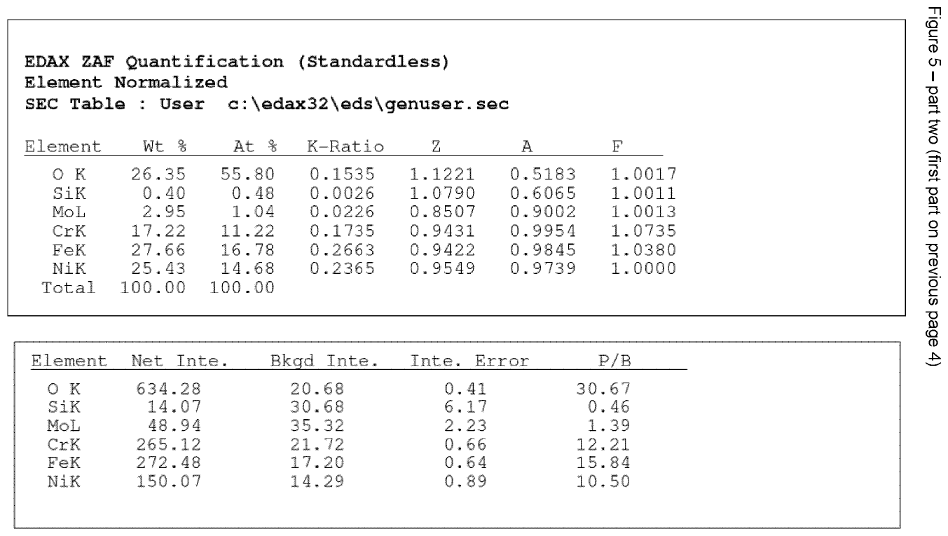

FIG. 4 shows another picture of the surface of a coated layer with higher magnification.

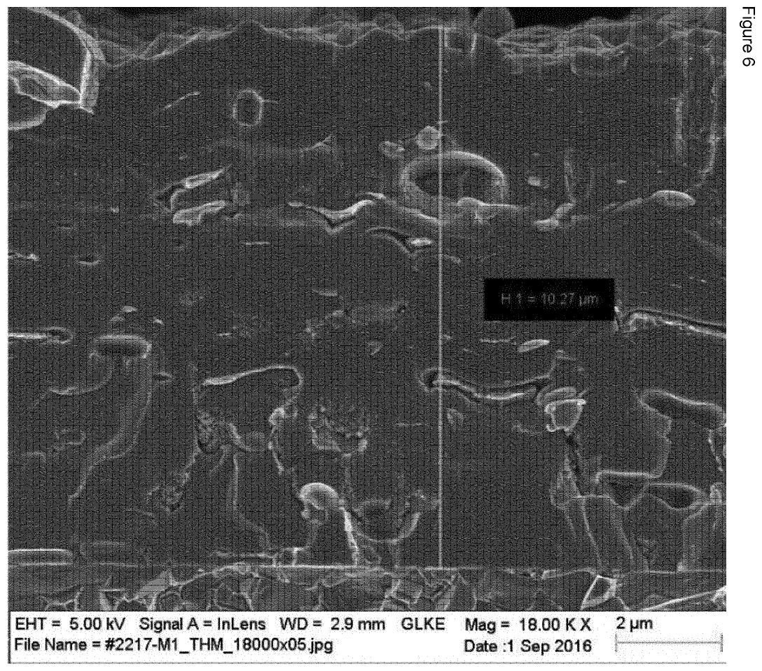

FIG. 5 shows an EDX, showing the chemical composition of the coated layer at the surface.

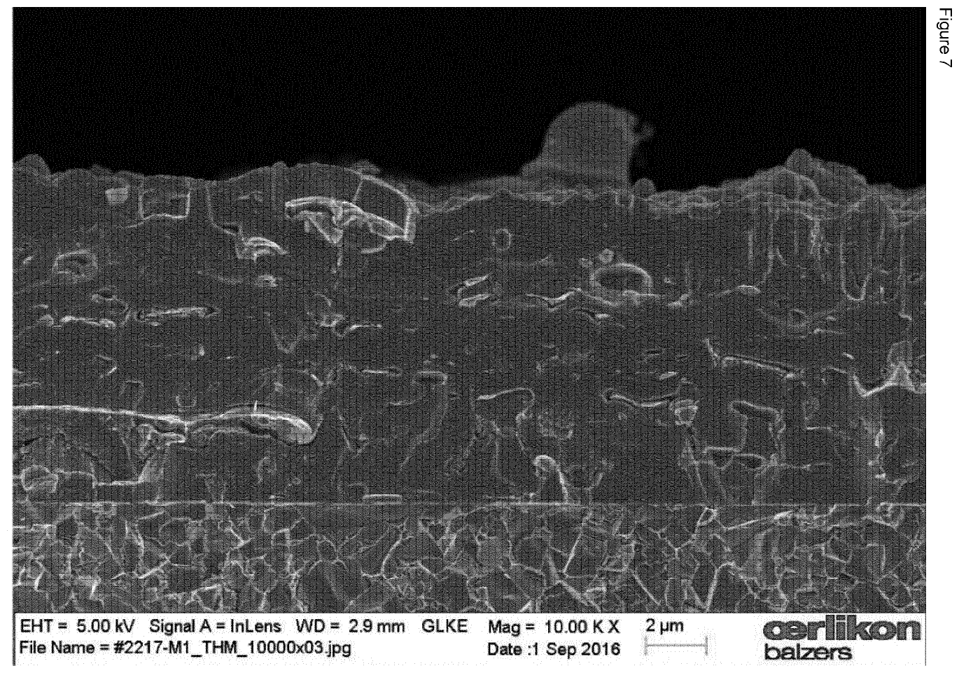

FIG. 6 shows an SEM of a fracture cross-section of a layer coated with a target according to the invention at high magnification.

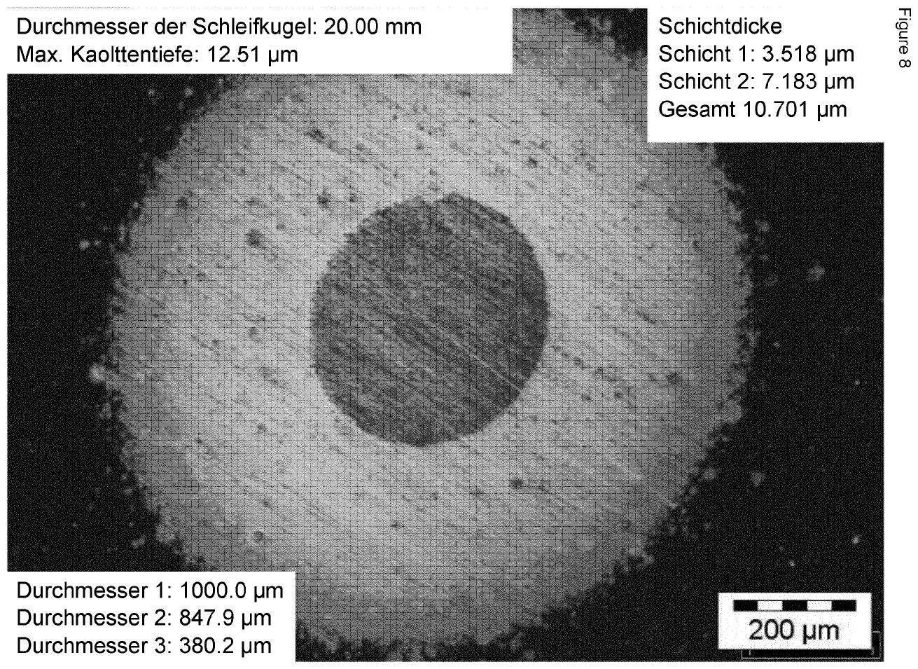

FIG. 7 shows another SEM of a layer coated with a target according to the present invention at lower magnification with respect to FIG. 6.

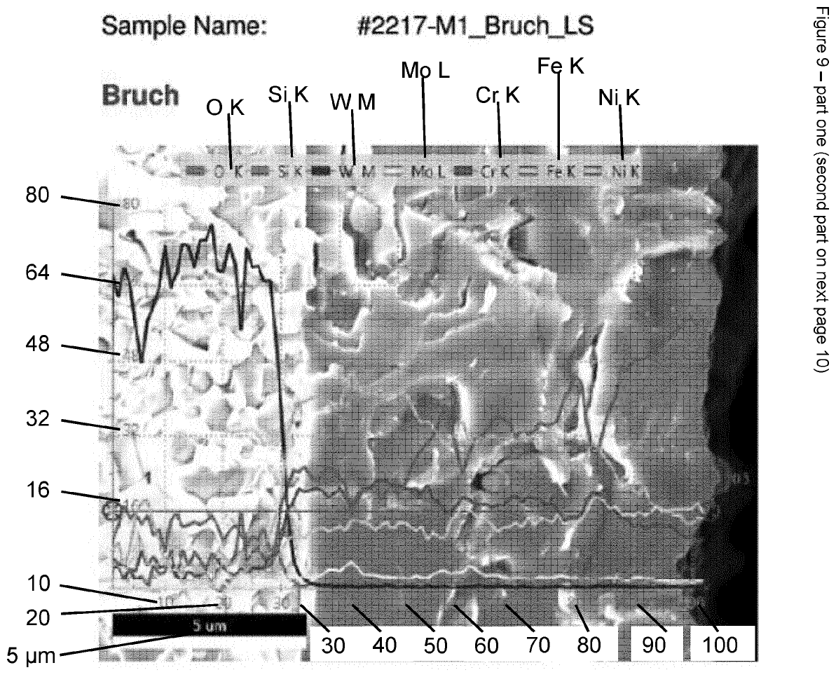

FIG. 8 shows the so-called calotte crater profile obtained by calotte grinding of a coated layer.

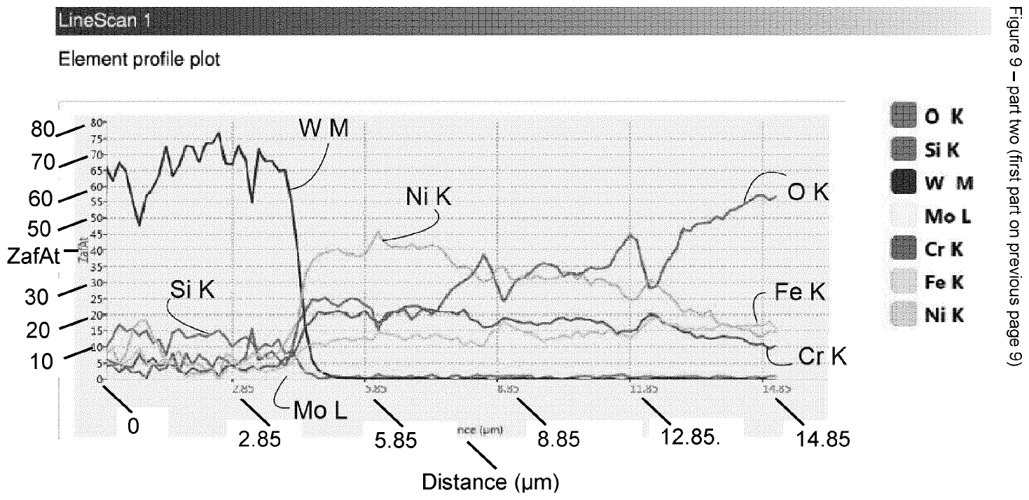

FIG. 9 shows the EDX line scan along the cross section of the coated layer.

According to the following example a target base plate was coated with a laser cladding method. The cladding material comprised 21.5% Ni, 8.5% Cr, 3.5% Mo, 3% Nb and the rest Fe. It was a standard size powder. Oerlikon Metco is selling this powder under the trade name MetcoClad 625F.

MetcoClad 625F was added to the surface on a base plate suitable for being fixed into a bayonet fixture. The method for adding the material to the surface was laser cladding.

FIG. 1 shows the resulting unused target. After production the target was slightly bend. However it could be easily flattened mechanically in a sufficient manner, suitable for inserting it into the arc evaporation coating machine. This already shows the excellent adhesion of the laser cladded coating at the metallic base plate. The target was inserted into the coating machine and a coating layer of approximately 10 μm was deposited without incurring any problems. To test the reliable operation in non-reactive as well as reactive arc evaporation, the target was operated in the beginning without oxygen and then successively oxygen flow was added to the arc evaporation resulting in a successively oxidized layer during growth towards the layer surface.

FIG. 2 shows the target after it was used for deposition. The target surface as well did not show any problems.

Then the inventors analyzed the coated layer. FIGS. 3 and 4 show the surface of the coated layer. As can be seen the coating process resulted in a rough surface with the coating comprising a considerable amount of droplets. This however is not always a disadvantage.

An EDX for measuring the chemical composition of the layer surface as coated was performed. This is shown in FIG. 5. The EDX shows an oxidized layer surface. The chemical composition of the metallic constituents in the oxidized layer are in fair agreement with the MetcoClad 625F powder which was used for laser cladding. As mentioned before, the layer was produced ramping up oxygen in order to test the process stability in non-reactive (without oxygen) and reactive (with different oxygen flows) atmosphere. In FIG. 8, the callotte crater profile indicates a change in morphology after 7.2 μm by color change towards the surface near layer region (3.5 μm) which is a result of the oxygen ramping during deposition.

In order to show the morphology of the coatings as deposited SEM pictures of two cross-sections of the layer as deposited were taken. They are shown in FIGS. 6 and 7. The change in morphology can also in this cross-section micrograph adumbrated (FIG. 6, after approx. 7 μm).

FIG. 9 shows the EDX line-scan across the coating layer and clearly indicates the oxygen ramp in the layer.

1. A method for building up and/or finalizing a PVD target, comprising using an additive method to add a target material.

2. The method according to claim 1, wherein the additive method is selected from the group of methods consisting of thermal spray method, conventional laser cladding method, extreme high speed laser cladding method, 3D printing method, and combinations thereof.

3. The method according to claim 1, comprising using a combination of materials during at least part of the additive method to build up and/or finalize the PVD target.

4. The method according to claim 1, wherein the additive method is based on powder material and the powder is a powder mixture.

5. The method according to claim 1, wherein during the additive method predefined microgaps are realized.

6. The method according to claim 1, wherein the method is a method to repair and/or to refill the target.

7. The method according to claim 1, wherein a target base plate is coated with the additive method to completely realize a new target.

8. The method according to claim 1, wherein the target comprises a target base plate and target material, and the target material is added to the base plate.

9. The method according to claim 1, wherein after the target material has been added, the target is mechanically flattened.

10. A target comprising a target base plate and a target material, wherein the target material lies directly on the target base plate, and the target base plate has a different material than the target material, and wherein the target material is added to the target base plate by using a method according to claim 1.

11. A method of using a 3-D-printing method for improving a thermal and/or electrical contact achieved in the course of building up and/or finalizing and/or repairing and/or refilling a target which comprises a base plate and a target material carried by the base plate, the method comprising 3-D-printing the required target material onto the base plate and/or onto the target material already carried by the base plate even if the target material onto which the 3-D-printing is accomplished has itself not been 3-D-printed.
